(19) United States
(12) Patent Application Publication
(10) Pub. No.: US 2026/0260104 A1
(43) Pub. Date: Sep. 3, 2026

(54) An in-memory computing circuit implemented based on acceleration of a BNN algorithm

(71) Applicant: INSTITUTE OF MICROELECTRONICS OF THE CHINESE ACADEMY OF SCIENCES, Beijing (CN)

(72) Inventors: Feng ZHANG, Beijing (CN); Xiaofan SUN, Beijing (CN); Di GENG, Beijing (CN); Shuaidi ZHANG, Beijing (CN); Weiye TANG, Beijing (CN)

(73) Assignee: INSTITUTE OF MICROELECTRONICS OF THE CHINESE ACADEMY OF SCIENCES, Beijing (CN)

(21) Appl. No.: 18/863,632

(22) PCT Filed: Oct. 27, 2023
(86) PCT No.: PCT/CN2023/126983

§ 371 Date: Nov. 6, 2024

(30) Foreign Application Priority Data
Aug. 15, 2023 (CN) 202311026276.2

(51) Int. Cl. G06N 3/063; G06F 7/544; G11C 13/00

(52) U.S. Cl. CPC G06N 3/063; G06F 7/5443; G11C 13/0009

(57) ABSTRACT

The present application relates to an in-memory computing circuit implemented based on acceleration of BNN algorithm includes: a first and second algorithm network are selected within a flexible RRAM storage array; data of a plurality of rows is input into the first algorithm network and a multiplier and accumulator to obtain multiplication and addition results, which are then input into a shifter; shifter shifts the multiplication and addition results and output the shifted results to a adder-subtractor to obtain the addition results, which are then output to a comparator; comparator binarizes the addition results and outputs to the second algorithm network, which performs further computation to output cumulative current from a column, and sends them to a processor for max value comparison and output; the processor for max value comparison and output judges the maximum of cumulative current from the column as the classification result.

### TECHNICAL FIELD

The present application relates to the field of integrated circuit technology, and particularly relates to an in-memory computing circuit implemented based on acceleration of a BNN algorithm.

### BACKGROUND

With the rapid development of deep neural network technologies for artificial intelligence, current floating-point (real-value) neural network faces problems of high memory consumption and low computation speed, which need to be addressed urgently. Developers aim to apply neural network models to embedded devices or mobile scenarios to solve real-time problems, fetch-as-you-go. Binarized Neural Network (BNN) is emerged.

Binarized Neural Network (BNN) is the neural network which uses only the two values “+1” and “−1” to represent weights and activations. In contrast to full-precision neural network, it allows convolution operations to be implemented using the simple combination of XNOR+popcount instead of multiplication and addition of float32, memory and computation have been significantly saved. This greatly facilitates the deployment of the model on resource-constrained devices, highly suitable for edge computing application scenarios. However, due to the limited information that binary values can represent, BNN typically has much lower model accuracy compared to full-precision models. Current research on BNN focuses on the following two main aspects: how to improve BNN accuracy and how to deploy them on low-power consumption and resource-constrained platforms effectively. The traditional von Neumann architecture is constrained by the “memory wall bottleneck”, resulting in high power consumption and slow speed. In-memory computing technology can implement more efficient computing systems and reduce computation power consumption. Since a plenty of convolution operations of multiplication and addition are a core component of deep learning algorithms, in-memory computing and in-memory logic are well-suited for deep neural network applications for artificial intelligence, including BNN, and AI-based big data technologies.

Currently, most of BNN algorithms implemented in RRAM compute-in-memory array are based on XNOR operations, realizing the RRAM array and peripheral circuits with a 2T2R structure. Therefore, to further improve energy efficiency without losing precision, there is an urgent need for an in-memory computing circuit implemented based on acceleration of a BNN algorithm.

### SUMMARY

In view of the above analysis, the embodiments of the present application aim at providing an in-memory computing circuit implemented based on acceleration of a BNN algorithm to solve the problems of large circuit area, high energy consumption and low compute-in-memory energy efficiency in existing circuits.

In one aspect, the embodiment of the present application provides an in-memory computing circuit implemented based on acceleration of a BNN algorithm, wherein the circuit comprises: a storage array of a flexible RRAM, a multiplication and addition module, a shifter, a comparator and a max value comparison output module;

according to a BNN network structure and input data, two regions configured to be selected within the storage array of the flexible RRAM as a first algorithm network and a second algorithm network respectively;

data of a plurality of rows at each bit position configured to be input into the first algorithm network and the multiplication and addition module; the first algorithm network configured to output the cumulative current from compute-in-memory units of each column to the multiplication and addition module, the multiplication and addition module configured to obtain the multiplication and addition results of each column based on the data of the plurality of rows and the cumulative current from each column, and input the multiplication and addition results of each column into the shifter;

the shifter configured to, based on the data of the plurality of rows being input to the bit positions, shift the multiplication and addition results of each column by the corresponding number of bits and output the shifted results to the adder-subtractor within the multiplication and addition module; the adder-subtractor configured to perform addition calculation on the shifted results of different bit positions for each column and output the addition results of each column to the comparator;

the comparator configured to binarize the addition results of each column to obtain the binarized results and output them to the second algorithm network;

the second algorithm network configured to perform further computation to output the cumulative current from each column and send them to the max value comparison output module;

the max value comparison output module configured to judge the maximum value of cumulative current from each column, the column with the maximum value is the classification result.

Further, wherein the multiplication and addition module further comprises: a popcount module and a multiplier;

the popcount module configured to receive input of the plurality of rows, obtain the number of “1” in the input of a plurality of rows and output the number of “1” to the multiplier;

the multiplier configured to multiply the number of “1” by a fixed value β and send the product result to the adder-subtractor;

the adder-subtractor configured to subtract the product result from a digital signal to obtain the matrix multiplication and addition result and send it to the shifter.

Further, wherein the circuit further comprises: a multiplexer selector MUX for a first column and a first analog-to-digital converter ADC;

the multiplexer selector MUX for the first column configured to sequentially select the compute-in-memory units of each column in the first algorithm network and send cumulative current from the selected column to the first analog-to-digital converter ADC;

the first analog-to-digital converter ADC configured to convert the cumulative current output by the first algorithm network into the digital signal and send it to the adder-subtractor.

Further, wherein the circuit further comprises: a multiplexer selector MUX for a second column and a second analog-to-digital converter ADC;

the multiplexer selector MUX for the second column configured to sequentially select the compute-in-memory units of each column in the second algorithm network and send cumulative current from the selected column to the second analog-to-digital converter ADC;

the second analog-to-digital converter ADC configured to convert the cumulative current output by the second algorithm network into the digital signal and send it to the max value comparison output module.

Further, wherein the circuit further comprises: a first data buffering module, a second data buffering module and a third data buffering module, all of them are used for temporary storage and integration of data;

the first data buffering module configured to receive the digital signal output by the first analog-to-digital converter ADC and after buffering, output it to the adder-subtractor;

the second data buffering module configured to receive the shifted result output by the shifter and after buffering, output it to the adder-subtractor;

the third data buffering module configured to receive the binarized result output by the comparator and after buffering, output it to the second algorithm network.

Further, wherein the adder-subtractor configured to perform addition or subtraction operations based on the control signal sent by an FPGA.

Further, wherein the shifter configured to shift the multiplication and addition results to the left by the corresponding bits based on the bit positions of data of a plurality of rows; for the multiplication and addition results corresponding to the i-th bit of the data of the plurality of rows, the shifter configured to shift the multiplication and addition results to the left by i bits, wherein 0≤i≤7.

Further, wherein a threshold is configured to be pre-set in the comparator; when the addition result is greater than the threshold, the comparator is configured to output 1; when the addition result is less than the threshold, the comparator configured to output 0.

Further, wherein a compute-in-memory array of the flexible RRAM comprises n×m compute-in-memory units;

the word lines WL for the compute-in-memory units of each row are connected in sequence, the source lines SL for the compute-in-memory units of each column are connected in sequence, the bit lines BL for the compute-in-memory units of each column are connected in sequence, the bit lines BL are used to output the computing results of the compute-in-memory units of that column;

each of the compute-in-memory units is a 1T1R structure, including one transistor and one memristor.

Further, wherein the transistor is an indium gallium zinc oxide based thin-film transistor IGZO TFT, the memristor is RRAM;

the gate of the indium gallium zinc oxide based thin-film transistor IGZO TFT is connected to the word line WL for the compute-in-memory units, the drain thereof is connected to the bit line BL for the compute-in-memory units, the source thereof is connected to one end of the memristor RRAM, the other end of the memristor RRAM is connected to the source line SL for the compute-in-memory units.

Compared with existing technology, the present application achieves at least one of the following beneficial effects:
1. By using the compute-in-memory array of flexible RRAM with a 1T1R unit structure, where both the indium gallium zinc oxide based thin-film transistor IGZO TFT and the memristor RRAM in the 1T1R unit structure are both flexible structures, the present application reduces the area of the compute-in-memory array by half without affecting computational accuracy comparing with the traditional 2T2R structure, further enhances energy efficiency, and its flexibility makes it more suitable for creating electronic skin.
2. The design of peripheral circuits such as the ADC, popcount module, multiplier and subtractor can completely compute the entire BNN algorithm and can handle multiple bit inputs, enhanced the computational precision and accuracy of the hardware circuit implementation of the BNN algorithm.

In the present application, the above technical solutions can be combined, to implement more preferred combined solutions. Other features and advantages of the present application will be described in the subsequent specification, and part of the advantages can become apparent from the specification, or be understood through the implementation of the present application. The objects and other advantages of the present application can be implemented and obtained from the contents particularly illustrated in the specification and the drawings.

### BRIEF DESCRIPTION OF DRAWINGS

The drawings are merely for the purpose of illustrating the particular embodiments, and are not considered as limitation to the present application. Throughout the drawings, the same reference signs denote the same elements.

FIG. 1 is a diagram of overall circuit architecture provided by the present application;

FIG. 2 is a data flow diagram of the BNN algorithm implementation provided by the present application;

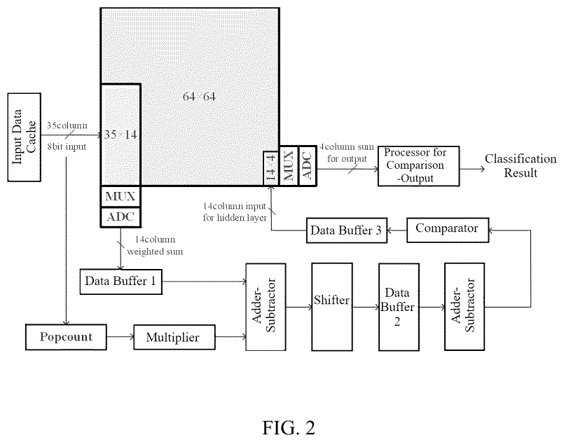

FIG. 3 is a circuit structure diagram of the compute-in-memory array of the flexible RRAM;

FIG. 4 is a calculation encoding table of the compute-in-memory array of RRAM based on the 1T1R structure.

### DESCRIPTION OF EMBODIMENTS

The preferable embodiments of the present application will be particularly described below by referring to the drawings. The drawings form part of the present application, are used to explain the principle of the present application together with the embodiments of the present application, and are not limiting the scope of the present application.

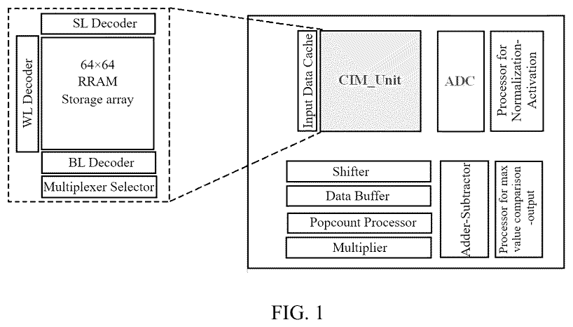

A particular embodiment of the present application discloses an in-memory computing circuit implemented based on acceleration of a BNN algorithm, as shown in FIG. 1. The circuit comprises: a storage array of flexible RRAM, a multiplication and addition module, a shifter, a comparator and a max value comparison output module;

according to a BNN network structure and input data, two regions are selected within the storage array of the flexible RRAM as a first algorithm network and a second algorithm network respectively;

data of a plurality of rows at each bit position are input into the first algorithm network and the multiplication and addition module; the first algorithm network outputs the cumulative current from compute-in-memory units of each column to the multiplication and addition module, the multiplication and addition module obtains the multiplication and addition results of each column based on the data of the plurality of rows and the cumulative current from each column, and inputs the multiplication and addition results of each column into the shifter;

the shifter, based on the bit positions input by the data of the plurality of rows, shifts the multiplication and addition results of each column by the corresponding number of bits and outputs the shifted results to the adder-subtractor within the multiplication and addition module; the adder-subtractor performs addition calculation on the shifted results of different bit positions for each column and outputs the addition results of each column to the comparator;

the comparator binarizes the addition results of each column to obtain the binarized results and outputs them to the second algorithm network; the second algorithm network performs further computation to output the cumulative current from each column and sends them to the max value comparison output module;

the max value comparison output module judges the maximum value of cumulative current from each column, the column with the maximum value is the classification result.

Specifically, according to the network structure of the BNN algorithm and the number of the input data, two regions are selected in the storage array of the flexible RRAM as a first algorithm network and a second algorithm network.

Specifically, the rows and columns of the first algorithm network are determined based on the number of input data rows and the size of the hidden layer separately, thereby determining the size of the first algorithm network. The rows and columns of the second algorithm network are determined based on the size of the hidden layer and the number of output data in the output layer, thereby determining the size of the second algorithm network.

Further, wherein the compute-in-memory array of the flexible RRAM comprises n×m compute-in-memory units;

the word lines WL for the compute-in-memory units of each row are connected in sequence, the source lines SL for the compute-in-memory units of each column are connected in sequence, the bit lines BL for the compute-in-memory units of each column are connected in sequence, the bit lines BL are used to output the computing results of the compute-in-memory units of that column;

each of the compute-in-memory units is a 1T1R structure, including one transistor and one memristor.

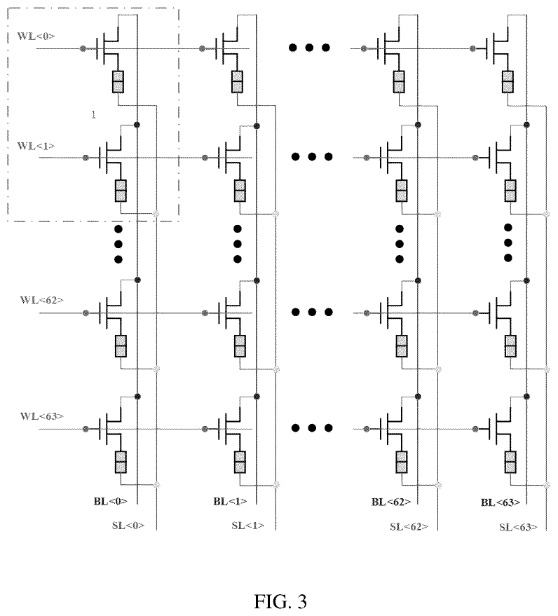

Preferably, as shown in FIG. 3, the size of the compute-in-memory array of the flexible RRAM is 64×64, with a total capacity of 4 Kb; it forms a multiplication and addition computation unit in conjunction with peripheral circuits such as a word line decoder, a bit line decoder and a source line decoder. The word line decoder, bit line decoder and source line decoder decode address signals given by an external FPGA to complete read and write operations.

Specifically, wherein the transistor is an indium gallium zinc oxide based thin-film transistor IGZO TFT, the memristor is RRAM;

the gate of the indium gallium zinc oxide based thin-film transistor IGZO TFT is connected to the word line WL for the compute-in-memory units, the drain thereof is connected to the bit line BL for the compute-in-memory units, the source thereof is connected to one end of the memristor RRAM, the other end of the RRAM is connected to the source line SL for the compute-in-memory units.

Specifically, wherein the operating modes of the compute-in-memory array of the flexible RRAM include a weight writing mode and an inference operation mode.

Specifically, when the bit line BL or source line SL is connected to the write voltage Vw, the working mode of the compute-in-memory array of the flexible RRAM is the weight writing mode. When the bit line BL is connected to the read voltage Vr, the working mode of the compute-in-memory array of the flexible RRAM is the inference operation mode.

Specifically, by controlling the input voltages of the word line WL, the bit line BL and the source line SL connected to the array through peripheral fpga, that is, the word line WL connects to a high or low level, thereby controlling the on/off state of the transistor and selecting whether the current compute-in-memory unit is activated or not. When the word line WL is connected to a high level, the transistor is on, meaning the compute-in-memory unit is activated. When the word line WL is connected to a low level, the transistor is off, meaning the compute-in-memory unit is not activated.

Specifically, in the weight writing mode, by controlling the connection voltage of the word line WL, the bit line BL and the source line SL, the resistance state of the memristor RRAM is changed, thereby achieving weight writing.

Specifically, when the word line WL is connected to a high level, the bit line BL is connected to the write voltage Vw and the source line SL is grounded, the conductance state of the memristor RRAM is in the low resistance state LRS, assigning β+1 to its weight;

when the word line WL is connected to a high level, the bit line BL is grounded and the source line SL is connected to the write voltage Vw, the conductance state of the memristor RRAM is in the high resistance state HRS, assigning β-1 to its weight;

when the word line WL is connected to a low level, indicating that the memristor RRAM is not selected, the resistance state of the memristor RRAM remains unchanged.

In the weight-writing mode, the high and low resistance states of the RRAM are set by controlling the write voltage Vw of the compute-in-memory unit and the on-off state of the transistor, completing the deployment of weights in the RRAM array. The output of the source line SL and the bit line BL are grounded or connected to write voltage, and the word line WL controls the on-off state of the transistor to control the weight writing of the RRAM in the compute-storage unit. For example, when the word line WL<0> is connected to high potential, the source line SL is connected to ground, and the bit line BL is connected to write voltage, the RRAM is programmed as a low resistance state.

Specifically, in the weight writing mode and the inference operation mode, because the memristor RRAM is a non-volatile component, once the resistance state of the RRAM is set in the weight writing mode, the resistance state of the memristor RRAM remains fixed and does not change unless a new programming voltage is applied to the word line WL, the bit line BL and the source line SL.

Specifically, the weight writing mode adopts a half-voltage method, wherein the write voltage Vw is greater than the threshold voltage of the memristor RRAM, and half of the write voltage Vw is less than the threshold voltage of the memristor RRAM, to ensure that the state of unselected memristors RRAM remains unchanged.

Specifically, in the inference operation mode, the bit line BL is connected to the read voltage Vr and the source line SL is grounded, the input of the compute-in-memory unit is determined based on whether the word line WL is connected to a high or a low level, the current output by the compute-in-memory unit is taken as the product of the inputted of the compute-in-memory unit and the weight of the memristor RRAM, the currents outputted by each compute-in-memory unit in the compute-in-memory units of each column are converged in the bit line corresponding to the compute-in-memory units of that column, so that the bit line output is the sum of the products of each unit in the compute-in-memory units of that column.

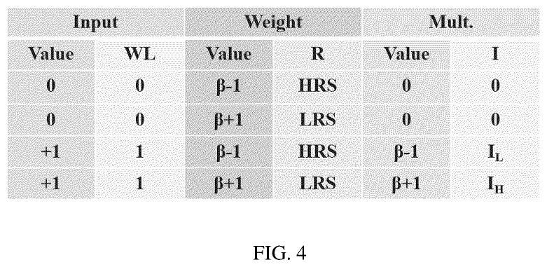

Specifically, as shown in FIG. 4, when the word line WL is connected to a high level and the resistance state of the memristor RRAM is in the high resistance state HRS, the input of the compute-in-memory unit is 1, the output is a low current IL, where the value of the low current IL is β-1;

when the word line WL is connected to a high level and the resistance state of the memristor RRAM is in the low resistance state LRS, the input of the compute-in-memory unit is 1, the output is a high current I_{H}, where the value of the high current I_{H} is β+1;

when the word line WL is connected to a low level, the indium gallium zinc oxide based thin-film transistor IGZO TFT is turned off, the compute-in-memory unit is not connected, the input of the compute-in-memory unit is 0, then the output current of the compute-in-memory unit is 0.

In the inference operation mode, the entire RRAM array can achieve multiplication and addition calculations. By controlling the on/off state of the TFT transistor through the word line WL, the input is realized: when the word line WL is connected to a high level, the TFT transistor is on, meaning the compute-in-memory unit is activated and the input is 1; when the word line WL is connected to a low level, the transistor is off, meaning the unit is not connected and the input is 0. The source line SL is grounded, the bit line BL is connected to the read voltage Vr and receives the corresponding accumulated current, which is the multiplication and addition result. The high or low resistance state of the RRAM via programming represents the weight distribution. When one bit line BL for the RRAM array is selected, it will generate a current I_{H} or IL based on the high or low resistance state. For example, when the word line WL<0> is connected to a high level, and the RRAM is in a high resistance state, the compute-in-memory unit generates a reference current IL, representing the computation result of the unit is β−1 (β>1). In the similar way of computing the compute-in-memory units of whole column, the accumulated current obtained at the output bit line BL represents the multiplication and addition result of the compute-in-memory units in that column. Thus, a compute-in-memory unit can be formed using only one TFT transistor and one RRAM, thereby forming a compute-in-memory array.

Specifically, where the β>1, the present application corresponds to a modified binary computation. The input of the word line WL controls whether the transistor is on or off. In the weight writing mode, the high and low resistance states of the memristor RRAM are determined by controlling the voltages applied to the bit line BL and source line SL. Since both the high and low resistance states are actually positive values, the low resistance state and high resistance state are encoded as β+1 and β−1 respectively. In the inference operation mode, the output also changes accordingly, the output is binary high current and low current too.

Further, wherein the multiplication and addition module further comprises: a popcount module and a multiplier;

the popcount module receives input of a plurality of rows to obtain the number of “1” in the input of a plurality of rows and outputs the number of “1” to the multiplier;

the multiplier multiplies the number of “1” by a fixed value B and sends the product result to the adder-subtractor;

the adder-subtractor subtracts the product result from the digital signal to obtain the matrix multiplication and addition result and sends it to the shifter.

Specifically, the multiplier is configured to multiply the input by a fixed β value to solve the weight setting problem, wherein B is determined by the performance of the compute-in-memory array of the RRAM,

$$β = ( {I}_{H} + {I}_{L} ) / ( {I}_{H} - {I}_{L} ) .$$

For example, if the matrix multiplication is [1,0,1,0,1] * [+1, +1, −1, −1, −1], that is, the input of a plurality of rows is [1,0,1,0,1], the weights of the RRAM compute-in-memory array of a certain column is [+1, +1, −1, −1, −1], the multiplication and addition result is −1, input of the multiple rows of corresponding compute-in-memory array of the RRAM are 10101, the resistance states input to the corresponding RRAM units are β+1, 3+1, β−1, β-1, β-1 respectively. Then the accumulated current output from the RRAM compute-in-memory array of that column is inputted to the multiplexer selector, the multiplexer selector selectively outputs the accumulated current from that column to the ADC for conversion. The ADC outputs a current digital signal with a magnitude of 3β−1 to the adder-subtractor. The popcount module outputs 3, the multiplier outputs 3β, then the adder-subtractor performs subtraction to output −1, showing that this solution matches the original multiplication and addition result exactly.

Further, wherein the circuit further comprises: the multiplexer selector MUX for a first column and the first analog-to-digital converter ADC;

the multiplexer selector MUX for first column sequentially selects the compute-in-memory units of each column in the first algorithm network and sends the cumulative current from the selected column to the first analog-to-digital converter ADC;

the first analog-to-digital converter ADC converts the cumulative current output by the first algorithm network into a digital signal and sends it to the adder-subtractor.

Further, wherein the adder-subtractor performs addition or subtraction operations based on the control signal provided by an FPGA.

Specifically, the adder-subtractor module adopts a carry lookahead adder structure, capable of performing addition and subtraction of two signed numbers. Whether addition or subtraction is performed is controlled according to the control signal from the FPGA. Since the compute-in-memory array of the RRAM encodes weights using all positive numbers during the hardware implementation, which are greater than the actual weights in the algorithm, the multiplication and addition results from the RRAM array need to be adjusted by subtracting the output result of the popcount module from the multiplication and addition results. Thus, subtraction is performed at this moment. This implementation splits the input into each bit position for input, therefore, addition is required to sum the results of each bit position to obtain the calculation result of the complete input. Thus, addition is performed at this moment.

Further, wherein the circuit further comprises: a first data buffering module, a second data buffering module and a third data buffering module, all of them are used for temporary storage and integration of data;

the first data buffering module receives the digital signal output by the first analog-to-digital converter ADC, and outputs it to the adder-subtractor after buffering;

the second data buffering module receives the shifted result output by the shifter, and outputs it to the adder-subtractor after buffering;

the third data buffering module receives the binarized result output by the comparator, and outputs it to the second algorithm network after buffering.

Further, wherein the circuit further comprises: the multiplexer selector MUX for the second column and the second analog-to-digital converter ADC;

the multiplexer selector MUX for the second column sequentially selects the compute-in-memory units of each column in the second algorithm network and sends the cumulative current from the compute-in-memory units of the selected column to the second analog-to-digital converter ADC;

the second analog-to-digital converter ADC converts the cumulative current output by the second algorithm network into a digital signal and sends it to the max value comparison output module.

Further, wherein the shifter shifts the multiplication and addition results to the left by the corresponding number of bits based on the bit positions input by the data of a plurality of rows; for the multiplication and addition results corresponding to the i-th bit of the data of the plurality of rows, the shifter shifts the multiplication and addition results to the left by i bit;

$$wherein 0 ⩽ i ⩽ 7.$$

Specifically, the shifter is used for shifting signed number, replacing multiplication operations.

Further, wherein a threshold is pre-set in the comparator; when the addition result is greater than the threshold, the comparator outputs 1; when the addition result is less than the threshold, the comparator outputs 0.

Specifically, the comparator implements normalization and binarization of data for use by the next layer of the network.

The max value comparison output module can perform a comparison of the max value of the four outputs data from the final layer of the network, used as the output of the classification result.

For example, in a BNN network, if the hidden layer size is 14, the input data is 8-bit data for 35 rows, output of the BNN network is 4. Therefore, the required algorithm network includes two fully connected layers of sizes 35*14 and 14*4, the mapping to the circuit is implemented as two RRAM arrays of sizes 35*14 and 14*4. So according to the above BNN network structure and input data, in the storage array of the flexible RRAM, a region 35*14 is selected as the first algorithm network, and a region 14*4 is selected as the second algorithm network. The first input to the storage array of the flexible RRAM is 8-bit input data for 35 rows, reused for weights. Each bit position for 35 rows is written into the first algorithmic network through the word line decoder in eight times, which means that the input data is each bit position data for the plurality of rows (35 rows). After computation through the first algorithm network, the multiplication-addition result is obtained. Then the multiplexer selector MUX for the first column connects with the first analog-to-digital converter ADC to obtain the analog-to-digital conversion results of cumulative current from each column. The analog-to-digital conversion results are stored in data buffering module 1. The output of data buffering module 1 is connected to the adder-subtractor. Meanwhile, each bit position for 35 rows is connected to the popcount module when inputting, the popcount module counts the number of “1” in each bit position of input of a plurality of rows. The output of the popcount module is connected to the multiplier, the number of “1” is multiplied by a fixed β value in the multiplier. The output of the multiplier is connected to the adder-subtractor. The FPGA initially sets the adder-subtractor to subtraction operations, subtracting the output of the multiplier from the output of the data buffering module 1 to obtain the multiplication-addition results of each bit position for 35 rows. The multiplication-addition results of each column corresponding to each bit position are inputted into the shifter, where each bit position achieves corresponding shifting. For example, the 0th bit position shifts 0 bit to the left, while the 7th bit position shifts 7 bits to the left. The shifted results of each bit position for each column are stored in data buffering module 2. For instance, it's the 0th bit, the input data of the shifter is 00000010, the shifter shifts 0 bit, the data is 00000010 after shifting; if it's the 3rd bit, the input data of the shifter is 00000010, the shifter shifts 3 bits, the data is 00010000 after shifting. After completing the above operations for the 8 bit positions, the obtained shifted results are all stored in data buffering module 2. The shifted results stored in data buffering module 2 are then inputted into the adder-subtractor. The FPGA sets the adder-subtractor to addition operations, adding the shifted results of all bit positions of each column stored in data buffering module 2 to obtain the addition results for each column. The addition results are outputted to the comparator. Normalization is performed in the comparator, that is, comparing the addition results with a pre-set threshold. If the addition result is greater than the threshold, the comparator outputs 1; when the addition result is less than the threshold, the comparator outputs 0. For example, if the input addition result is 3 and the threshold is 1, the output is 1; if the input addition result is 0 and the threshold is 1, the output is 0. In this way, the binarized input for the next layer is obtained, which is the input data for the second algorithm network. The final layer does not perform binarization, it outputs the classification result directly through the max value comparison output module. It outputs 0 if the cumulative current value for the first column is the highest, in the similar way, it outputs 3 if the cumulative current value for the fourth column is the highest.

Compared with existing technology, an in-memory computing circuit implemented based on acceleration of a BNN algorithm provided by the embodiment uses the compute-in-memory array of the flexible RRAM with a 1T1R unit structure. The indium gallium zinc oxide based thin-film transistor IGZO TFT and the memristor RRAM in the 1T1R unit structure are both flexible. The present application reduces the area of the compute-in-memory array by half without affecting computational accuracy comparing with the traditional 2T2R structure, further enhances energy efficiency. Its flexibility makes it more suitable for creating electronic skin. The design of peripheral circuits such as the ADC, popcount module, multiplier and subtractor can completely implement the entire BNN algorithm and can handle multiple bit inputs, further enhanced the computational precision and accuracy of the hardware circuit implementation of the algorithm.

A person skilled in the art can understand that all or part of the process of implementing the methods of the above embodiments may be implemented by related hardware according to an instruction from a computer program, and the program may be stored in a computer-readable storage medium, wherein the computer-readable storage medium is a magnetic disc, an optical disc, a read-only memory, a random access memory and so on.

The above are merely preferable particular embodiments of the present application, and the protection scope of the present application is not limited thereto. All of the variations or substitutions that a person skilled in the art can easily envisage within the technical scope disclosed by the present application should fall within the protection scope of the present application.

1. An in-memory computing circuit implemented based on acceleration of a BNN algorithm, wherein the circuit comprises: a storage array of a flexible RRAM, a multiplier and accumulator, a shifter, a comparator and a processor for max value comparison and output;
according to a BNN network structure and input data, two regions configured to be selected within the storage array of the flexible RRAM as a first algorithm network and a second algorithm network respectively;
data of a plurality of rows at each bit position configured to be input into the first algorithm network and the multiplier and accumulator; the first algorithm network configured to output the cumulative current from compute-in-memory units of each column to the multiplier and accumulator, the multiplier and accumulator configured to obtain the multiplication and addition results of each column based on the data of the plurality of rows and the cumulative current from each column, and input the multiplication and addition results of each column into the shifter;
the shifter configured to, based on the bit positions input by the data of the plurality of rows, shift the multiplication and addition results of each column by the corresponding number of bits and output the shifted results to the adder-subtractor within the multiplier and accumulator; the adder-subtractor configured to perform addition calculation on the shifted results of different bit positions for each column and output the addition results of each column to the comparator;
the comparator configured to binarize the addition results of each column to obtain the binarized results and output them to the second algorithm network; the second algorithm network configured to perform further computation to output the cumulative current from each column and send them to the processor for max value comparison and output;
the processor for max value comparison and output configured to judge the maximum value of cumulative current from each column, the column with the maximum value is the classification result.

2. The in-memory computing circuit implemented based on acceleration of a BNN algorithm according to claim 1, wherein the multiplier and accumulator further comprises: a popcount processor and a multiplier;
the popcount processor configured to receive input of the plurality of rows, obtain the number of “1” in the input of a plurality of rows and output the number of “1” to the multiplier;
the multiplier configured to multiply the number of “1” by a fixed value β and send the product result to the adder-subtractor;
the adder-subtractor configured to subtract the product result from a digital signal to obtain the matrix multiplication and addition result and send it to the shifter.

3. The in-memory computing circuit implemented based on acceleration of a BNN algorithm according to claim 2, wherein the circuit further comprises: a multiplexer selector MUX for a first column and a first analog-to-digital converter ADC;
the multiplexer selector MUX for the first column configured to sequentially select the compute-in-memory units of each column in the first algorithm network and send cumulative current from the selected column to the first analog-to-digital converter ADC;
the first analog-to-digital converter ADC configured to convert the cumulative current output by the first algorithm network into the digital signal and send it to the adder-subtractor.

4. The in-memory computing circuit implemented based on acceleration of a BNN algorithm according to claim 3, wherein the circuit further comprises: a multiplexer selector MUX for a second column and a second analog-to-digital converter ADC;
the multiplexer selector MUX for the second column configured to sequentially select the compute-in-memory units of each column in the second algorithm network and send cumulative current from the selected column to the second analog-to-digital converter ADC;
the second analog-to-digital converter ADC configured to convert the cumulative current output by the second algorithm network into the digital signal and send it to the processor for max value comparison and output.

5. The in-memory computing circuit implemented based on acceleration of a BNN algorithm according to claim 4, wherein the circuit further comprises: a first data buffer, a second data buffer and a third data buffer, all of them are used for temporary storage and integration of data;
the first data buffer configured to receive the digital signal output by the first analog-to-digital converter ADC and after buffering, output it to the adder-subtractor;
the second data buffer configured to receive the shifted result output by the shifter and after buffering, output it to the adder-subtractor;
the third data buffer configured to receive the binarized result output by the comparator and after buffering, output it to the second algorithm network.

6. The in-memory computing circuit implemented based on acceleration of a BNN algorithm according to claim 5, wherein the adder-subtractor configured to perform addition or subtraction operations based on the control signal sent by an FPGA.

7. The in-memory computing circuit implemented based on acceleration of a BNN algorithm according to claim 6, wherein the shifter configured to shift the multiplication and addition results to the left by the corresponding bits based on the bit positions of data of a plurality of rows; for the multiplication and addition results corresponding to the i-th bit of the data of the plurality of rows, the shifter configured to shift the multiplication and addition results to the left by i bits, wherein 0≤i≤7.

8. The in-memory computing circuit implemented based on acceleration of a BNN algorithm according to claim 7, wherein a threshold is configured to be pre-set in the comparator; when the addition result is greater than the threshold, the comparator is configured to output 1; when the addition result is less than the threshold, the comparator configured to output 0.

9. The in-memory computing circuit implemented based on acceleration of a BNN algorithm according to claim 1, wherein a compute-in-memory array of the flexible RRAM comprises n×m compute-in-memory units;
the word lines WL for the compute-in-memory units of each row are connected in sequence, the source lines SL for the compute-in-memory units of each column are connected in sequence, the bit lines BL for the compute-in-memory units of each column are connected in sequence, the bit lines BL are used to output the computing results of the compute-in-memory units of that column;
each of the compute-in-memory units is a 1T1R structure, including one transistor and one memristor.

10. The in-memory computing circuit implemented based on acceleration of a BNN algorithm according to claim 9, wherein the transistor is an indium gallium zinc oxide based thin-film transistor IGZO TFT, the memristor is RRAM;
the gate of the indium gallium zinc oxide based thin-film transistor IGZO TFT is connected to the word line WL for the compute-in-memory units, the drain thereof is connected to the bit line BL for the compute-in-memory units, the source thereof is connected to one end of the memristor RRAM, the other end of the memristor RRAM is connected to the source line SL for the compute-in-memory units.
